(19) United States
(12) Patent Application Publication
(10) Pub. No.: US 2025/0098547 A1
(43) Pub. Date: Mar. 20, 2025

(54) MAGNETORESISTIVE EFFECT ELEMENT AND MAGNETIC MEMORY

(71) Applicant: TDK CORPORATION, Tokyo (JP)

(72) Inventors: Shuji OKAME, Tokyo (JP); Tomoyuki SASAKI, Tokyo (JP); Zhenyao TANG, Tokyo (JP)

(73) Assignee: TDK CORPORATION, Tokyo (JP)

(21) Appl. No.: 18/470,708

(22) Filed: Sep. 20, 2023

(51) Int. Cl. H10N 50/20; H10B 61/00; H10N 50/85

(52) U.S. Cl. CPC H10N 50/20; H10B 61/00; H10N 50/85

(57) ABSTRACT

The magnetic memory of the present disclosure comprises a plurality of magnetoresistive effect elements. Each of the magnetoresistive effect elements comprises a reference layer, a magnetization free layer, a tunnel barrier layer provided between the reference layer and the magnetization free layer, a first cap layer provided on the magnetization free layer, a second cap layer; and a ferromagnetic layer provided between the first cap layer and the second cap layer. The ferromagnetic layer has a thickness less than a thickness of the magnetization free layer.

### TECHNICAL FIELD

This disclosure relates to magnetoresistive effect elements and magnetic memories.

### BACKGROUND

Magnetic memory, such as MRAMs (Magnetoresistive Random Access Memory), is composed of a plurality of magnetoresistive effect elements. STT (Spin-Transfer Torque)-MRAM technology uses the spin-transfer torque characteristic to set the magnetic state of an MTJ (Magnetic Tunnel Junction).

### SUMMARY

The magnetic memory of the present disclosure comprises a plurality of magnetoresistive effect elements. Each of the magnetoresistive effect elements comprises a reference layer, a magnetization free layer, a tunnel barrier layer provided between the reference layer and the magnetization free layer, a first cap layer provided on the magnetization free layer, a second cap layer, and a ferromagnetic layer provided between the first cap layer and the second cap layer, the ferromagnetic layer having a thickness that is less than a thickness of the magnetization free layer.

### BRIEF DESCRIPTION OF THE DRAWINGS

FIG. 1 shows a longitudinal cross-sectional structure of the magnetoresistive effect element.

FIG. 2 shows a longitudinal cross-sectional structure of a base layer.

FIG. 3 shows a longitudinal cross-sectional structure of a reference layer.

FIG. 4 shows a longitudinal cross-sectional structure of the second cap layer.

FIG. 5A shows a longitudinal cross-sectional structure of a first cap layer and a ferromagnetic layer.

FIG. 5B shows a longitudinal cross-sectional structure of the first cap layer and the ferromagnetic layer.

FIG. 5C shows a longitudinal cross-sectional structure of the first cap layer and the ferromagnetic layer.

FIG. 6 shows a longitudinal cross-sectional view of the magnetoresistive effect element.

FIG. 7 shows a circuit diagram of the magnetic memory.

### DETAILED DESCRIPTION

The following embodiments are described with reference to the accompanying drawings. In the present specification and drawings, substantially the same constituent elements are denoted by the same reference numerals.

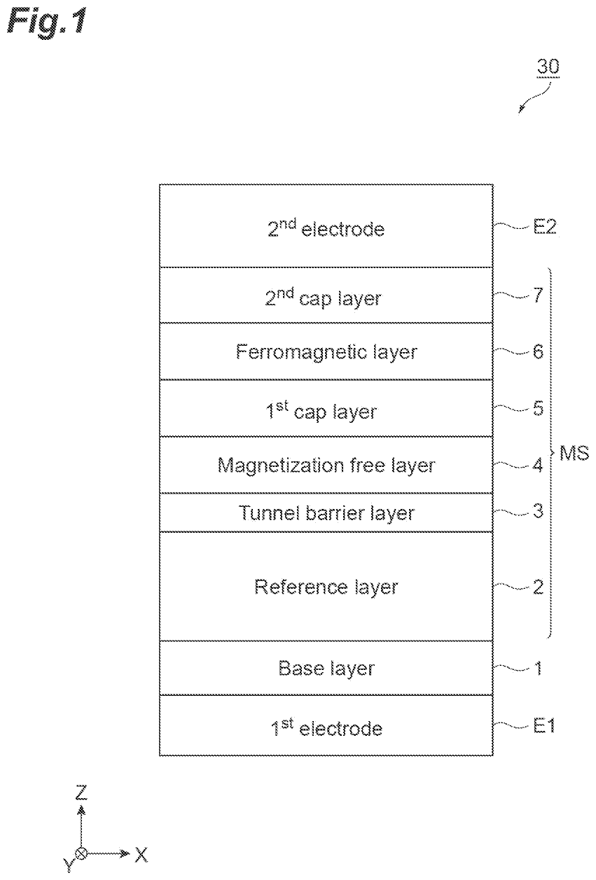

FIG. 1 shows a longitudinal cross-sectional structure of the magnetoresistive effect element.

The magnetoresistive effect element 30 is a tunnel magnetoresistive (TMR) element. The magnetoresistive effect element 30 comprises a base layer 1 and a main stack MS. The main stack MS comprises a reference layer 2, a tunnel barrier layer 3, a magnetization free layer 4, a first cap layer 5, a ferromagnetic layer 6, and a second cap layer 7. The base layer 1 is provided between a first electrode E1 and the reference layer 2. A second electrode E2 is provided on the second cap layer 7.

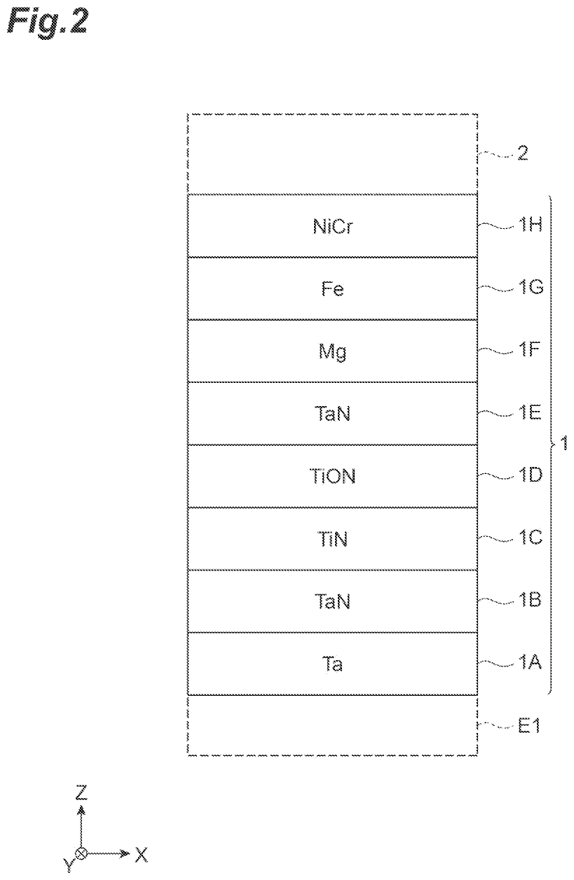

The base layer 1 is positioned between the first electrode E1 and the reference layer 2. The detailed structure of the base layer 1 is shown in FIG. 2.

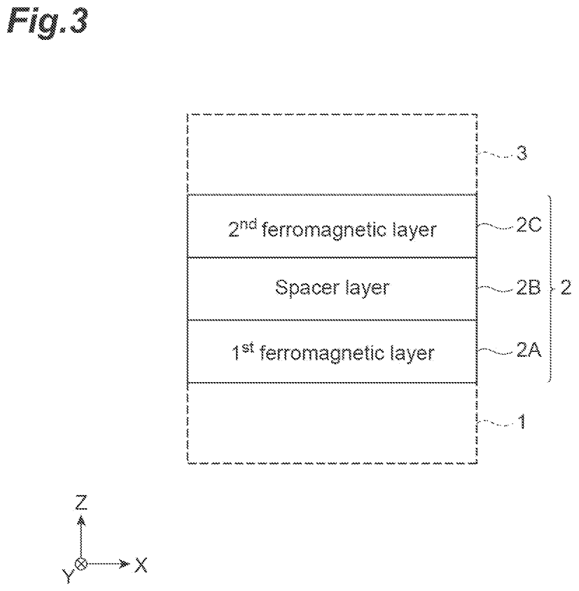

The reference layer 2 has a fixed magnetization direction. The thickness of the reference layer 2 may be from 3 nm to 26 nm. The detailed structure of the reference layer 2 is shown in FIG. 3.

The tunnel barrier layer 3 is provided between the reference layer 2 and the magnetization free layer 4. The tunnel barrier layer 3 passes electrons by using tunnel effect. The tunnel barrier layer 3 is comprised of an insulating material such as MgO. The insulating material of the tunnel barrier layer 3 is at least one material selected from the group consisting of MgO, Al₂O₃, ZnO, GaO_{X}, and MgAl₂O₄. Materials such as MgO can provide perpendicular magnetic anisotropy to the ferromagnetic material in the magnetization free layer 4 and the reference layer 2. These layers may also be formed to have in-plane anisotropy.

The magnetization free layer 4 comprises one or more ferromagnetic layers, and its magnetization direction can be easily changed. When the magnetization directions of the reference layer 2 and the magnetization free layer 4 are parallel, the magnetic resistance is low. On the other hand, when these directions are anti-parallel, the magnetic resistance is high.

The magnetic tunnel junction (MTJ) comprises the reference layer 2, the tunnel barrier layer 3, and the magnetization free layer 4. The magnetization free layer 4 includes Co (Cobalt). The magnetization free layer 4 may comprise at least two elements selected from the group consisting of Co, Ni (Nickel), Fe (Iron), and B (Boron).

The first cap layer 5 is provided on the magnetization free layer 4. The first cap layer 5 is comprised of a nonmagnetic material such as MgO. The first cap layer 5 comprises an oxide layer, a thickness of the oxide layer being less than a thickness of the tunnel barrier layer 3. The thickness of the first cap layer 5 is 0.5 nm or less. Since the first cap layer 5 is very thin, the amount of the material inside the first cap layer 5 is small. Therefore, the material diffusion from the first cap layer 5 to the tunnel barrier layer 3 can be suppressed. The suppression of the material migration can improve reliability of the magnetoresistive effect element. The thickness of the first cap layer 5 may be from 1 nm to 3 nm.

The first cap layer 5 includes an oxide of a first metal element, the tunnel barrier layer 3 includes an oxide of a second metal element. The first metal element (e.g. Mg (Magnesium)) and the second metal element (e.g. Mg) are identical. The oxide of the first metal element is MgO, and the oxide of the second metal element is MgO. When the first metal element ratio R_{first} is defined by N_{first}/Nₘₑₜₐₗ, the first metal element ratio R_{first} is 90% or greater. N_{first} indicates the number of atoms of the first metal element in the relevant metal oxide (first cap layer 5) and Nₘₑₜₐₗ indicates the number of atoms of metal element in the relevant metal oxide (first cap layer 5). When the second metal element ratio R_{second} is defined by N_{second}/Nₘₑₜₐₗ, the second metal element ratio R_{second} is 90% or greater. N_{second} indicates the number of atoms of the second metal element in the relevant metal oxide (tunnel barrier layer 3) and Nₘₑₜₐₗ indicates the number of atoms of metal element in the relevant metal oxide (tunnel barrier layer 3). Since the tunnel barrier layer 3 and the first cap layer 5 both include the same metal oxide (MgO), the first cap layer 5 may suppress the material diffusion from the tunnel barrier layer 3.

The ferromagnetic layer 6 is provided between the first cap layer 5 and the second cap layer 7. The material diffusion from the magnetization free layer 4 to the second cap layer 7 can be suppressed by the ferromagnetic layer 6 (diffusion suppression layer). The suppression of the material migration can increase reliability of the magnetoresistive effect element. The ferromagnetic layer 6 has a thickness less than a thickness of the magnetization free layer 4. In the embodiment, the thickness of the ferromagnetic layer 6 is 0.5 nm or less. The thickness of the ferromagnetic layer 6 is less than a thickness sufficient to cause self-magnetization in the ferromagnetic layer 6. Note that a cap layer including the first cap layer 5, the second cap layer 7 and the ferromagnetic layer 6 does not exhibit a magneto-resistive effect. Each of the cap layer and the ferromagnetic layer 6 is a dead layer in view from the magnetoresistive effect. Therefore, the cap layer and ferromagnetic layer 6 do not cause magnetic noise in the magnetization free layer 4. The thickness of the ferromagnetic layer 6 may be from 1 nm to 3 nm.

The ferromagnetic layer 6 includes Fe (Iron) and Co (Cobalt), and a concentration of Co (or composition ratio of Co/Fe) may decrease as the ferromagnetic layer 6 approaches the second cap layer 7. In this case, the magnetic noise in the magnetization free layer 4 caused by the ferromagnetic layer 6 can be reduced.

The second cap layer 7 is provided on the ferromagnetic layer 6. The second cap layer 7 comprises a nonmagnetic metal layer in contact with the ferromagnetic layer 6. This nonmagnetic metal layer comprises at least one element selected from the group consisting of Ru, Mo and W. The second cap layer 7 may include Ta. These materials can suppress the material diffusion between the electrode and MTJ.

FIG. 2 shows a longitudinal cross-sectional structure of the base layer 1.

The first electrode E1 is made of a nonmagnetic metal such as Al or Cu. The base layer 1 is provide on the first electrode E1. The base layer 1 includes Ta (Tantalum), N (Nitrogen), Ti (Titanium), O (Oxygen), Mg (Magnesium), Fe (Iron), Ni (Nickel), and Cr (Chromium). This is an example of the material combinations. The base layer 1 may omit one or more above elements. The base layer 1 may include further elements. The base layer 1 can act as a buffer layer.

A first layer 1A, a second layer 1B, a third layer 1C, a fourth layer 1D, a fifth layer 1E, a sixth layer 1F, a seventh layer 1G, and an eighth layer 1H are sequentially layered on the first electrode E1. The first layer 1A is made of Ta. The second layer 1B is made of TaN. The third layer 1C is made of TiN. The fourth layer 1D is made of TiON. The fifth layer 1E is made of TaN. The sixth layer 1F is made of Mg. The seventh layer 1G is made of Fe. The eighth layer 1H is made of NiCr. The second electrode is provided on the eighth layer 1H. The second electrode E2 is made of a nonmagnetic metal such as Al or Cu.

The base layer 1 comprises a first Ta-containing layer (layers 1A, 1B), a Ti-containing layer (layers 1C, 1D), and a second Ta-containing layer (layer 1E). The first Ta-containing layer (layers 1A, 1B) is provided on the first electrode E1. The Ti-containing layer (layers 1C, 1D) is provided on the first Ta-containing layer (layers 1A, 1B). The second Ta-containing layer (layer 1E) is provided on the Ti-containing layer (layers 1C, 1D). The first and the second Ta-containing layers (layers 1A, 1B, 1E) may reduce the lattice mismatch between adjacent layers. The Ti-containing layer (layers 1C, 1D), especially the titanium nitride layer interposed between the Ta-containing layers can function as a barrier metal.

The base layer 1 comprises the sixth layer 1F (Mg layer) provided on the fifth layer 1E (second Ta-containing layer), the seventh layer 1G (Fe layer) provided on the sixth layer 1F (Mg layer), and the eighth layer 1H (NiCr layer) provided on the seventh layer 1G (Fe layer). The NiCr layer (layer 1H) simultaneously serves as both an adhesion and resistance layer. The metal layer (layers 1F, 1G) is provided on the second Ta-containing layer. The metal layer (Mg and Fe layers 1F, 1G) may be used to improve lattice matching. The NiCr layer is provided on the metal layer. The Ta-containing layer can improve the characteristics such as magnetic stability of the magnetoresistive effect element. It should be noted that the above metal (Ta, Mg, Fe)-containing layer basically indicates the relevant metal (Ta, Mg, Fe) layer.

FIG. 3 shows a longitudinal cross-sectional structure of a reference layer 2.

The reference layer 2 comprises a first ferromagnetic layer 2A, a spacer layer 2B (interlayer), and a second ferromagnetic layer 2C. The first ferromagnetic layer 2A is made of a ferromagnetic material such as CoNi. The spacer layer 2B (nonmagnetic layer) is made of a nonmagnetic material such as Ir (Iridium). The second ferromagnetic layer 2C is made of a ferromagnetic material such as CoFeB. The first ferromagnetic layer 2A and the second ferromagnetic layer 2C are exchange-coupled via the spacer layer 2B. The thickness of the first ferromagnetic layer 2A (pinned layer) may be from 2 nm to 20 nm. The thickness of the spacer layer 2B may be from 0.2 nm to 3 nm. The thickness of the second ferromagnetic layer 2C (pinning layer) may be from 3 nm to 10 nm.

The first ferromagnetic layer 2A includes Co. The first ferromagnetic layer 2A may be comprised of at least two elements selected from the group consisting of Co, Ni, Fe and B. For example, the first ferromagnetic layer 2A may be CoNi, CoPt, or FePt. The second ferromagnetic layer 2C includes Co. The second ferromagnetic layer 2C may be comprised of at least two elements selected from the group consisting of Co, Ni, Fe and B. For example, the second ferromagnetic layer 2C may be CoFeB.

The spacer layer 2B is interposed between the first ferromagnetic layer 2A and the second ferromagnetic layer 2C. The nonmagnetic material of the spacer layer 2B may be a nonmagnetic metal material. The spacer layer 2B may be comprised of at least one element selected from the group consisting of Ir, Mo (Molybdenum), Rh (rhodium), and Ru (Ruthenium).

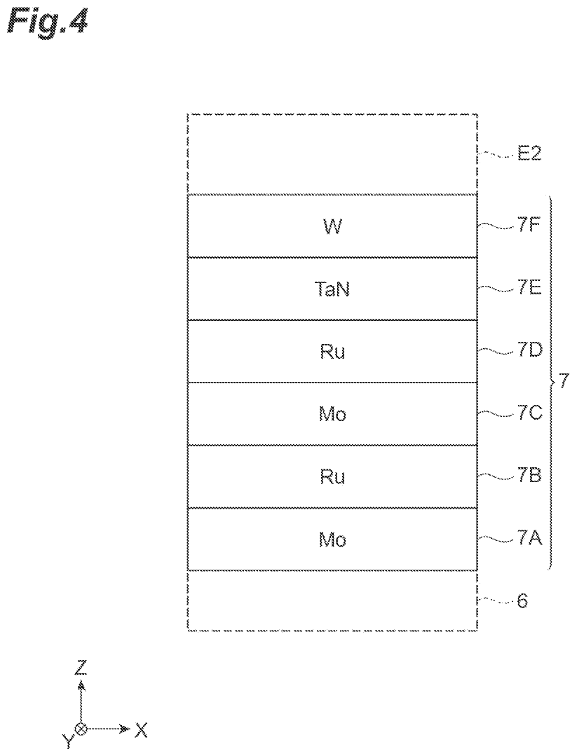

FIG. 4 shows a longitudinal cross-sectional structure of the second cap layer.

The second cap layer 7 includes the nonmagnetic metal layer. This nonmagnetic metal layer comprises a plurality of metal layers. The metal layers can reduce the material diffusion between the electrode and the MTJ. A first layer 7A, a second layer 7B, a third layer 7C, a fourth layer 7D, a fifth layer 7E, and a sixth layer 7F are layered in sequence on the ferromagnetic layer 6. The second cap layer 7 comprises these layers (7A to 7F). The first layer 7A is made of Mo. The second layer 7B is made of Ru. The third layer 7C is made of Mo. The fourth layer 7D is made of Ru. The fifth layer 7E is made of TaN. The sixth layer 7F is made of W (Tungsten). It should be Noted that the above metal (Mo, Ru, W)-containing layer (7A, 7B-7E, 7F) basically indicates the relevant metal (Mo, Ru, W) layer.

The cap layer blocks or suppresses impurity diffusion from outside. The second cap layer 7 can suppress the oxidation of the ferromagnetic material under the second cap layer 7. The cap layer structure is not limited by the above structure. For example, the second cap layer 7 may include further layers such as Pt (Platinum) and/or Pd (Palladium). Some of the materials of the second cap layer 7 may be replaced with other materials. The number of the layers of the second cap layer 7 can be increased or decreased.

The second cap layer 7 includes a hard mask layer in contact with the nonmagnetic metal layer. The hard mask layer comprises at least one of Ta and W. For example, the sixth layer 7F can be the hard mask layer. The hard mask layer protects the stack under the hard mask layer during an etching process. In the etching process, the adjacent portions outside the hard mask layer are etched.

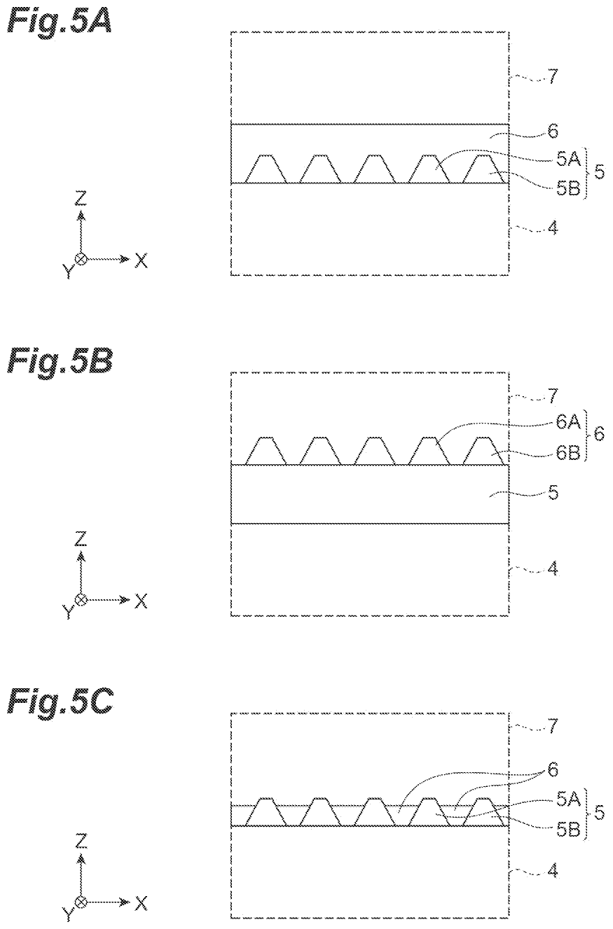

FIG. 5A shows a longitudinal cross-sectional structure of a first cap layer and a ferromagnetic layer.

As shown in FIG. 5A, the first cap layer 5 comprises a plurality of islands (5A, 5B) distributed two-dimensionally on the magnetization free layer 4. The islands (5A, 5B) are formed on the surface (XY plane) of the magnetization free layer 4. The height (thickness in Z-axis direction) of each of the islands (5A, 5B) is greater than 0 nm. The height (thickness in Z-axis direction) of each of the islands (5A, 5B) may be 0.5 nm or less. The height (thickness) of each of the islands (5A, 5B) may be 0.4 nm or less. The thickness of the ferromagnetic layer 6 may be greater than the thickness of each of the islands (5A, 5B). The thickness of the ferromagnetic layer 6 is greater than 0 nm. The thickness of the ferromagnetic layer 6 may be 0.5 nm or less. The structure of the islands can reduce the magnetic noise in the magnetization free layer 4 caused by the first cap layer 5.

FIG. 5B shows a longitudinal cross-sectional structure of the first cap layer and the ferromagnetic layer.

As shown in FIG. 5B, the ferromagnetic layer 6 comprises a plurality of islands (6A, 6B) distributed two-dimensionally on the first cap layer 5. The islands (6A, 6B) are formed on the surface (XY plane) of the first cap layer 5. The height (thickness in Z-axis direction) of each of the islands (6A, 6B) is greater than 0 nm. The height (thickness in Z-axis direction) of each of the islands (6A, 6B) may be 0.5 nm or less. The height (thickness) of each of the islands (6A, 6B) may be 0.4 nm or less. The thickness of the first cap layer 5 may be greater than the thickness of each of the islands (6A, 6B). The thickness of the first cap layer 5 is greater than 0 nm. The thickness of the first cap layer 5 may be 0.5 nm or less. The thickness of the first cap layer 5 may be greater than 0.5 nm. The structure of the islands can reduce the magnetic noise in the magnetization free layer 4 caused by the ferromagnetic layer 6.

FIG. 5C shows a longitudinal cross-sectional structure of the first cap layer and the ferromagnetic layer.

As shown in FIG. 5C, the first cap layer 5 comprises a plurality of islands (5A, 5B) distributed two-dimensionally on the magnetization free layer 4. The ferromagnetic layer 6 fills a space between the islands (5B, 5C). The islands (5A, 5B) are formed on the surface (XY plane) of the magnetization free layer 4. The height (thickness in Z-axis direction) of each of the islands (5A, 5B) is greater than 0 nm. The height (thickness in Z-axis direction) of each of the islands (5A, 5B) may be 0.5 nm or less. The height (thickness) of each of the islands (5A, 5B) may be 0.4 nm or less. The thickness of the ferromagnetic layer 6 may be less than the height of each of the islands (5A, 5B). The islands structure can reduce the magnetic noise in the magnetization free layer 4 caused by the first cap layer 5 and the ferromagnetic layer 6.

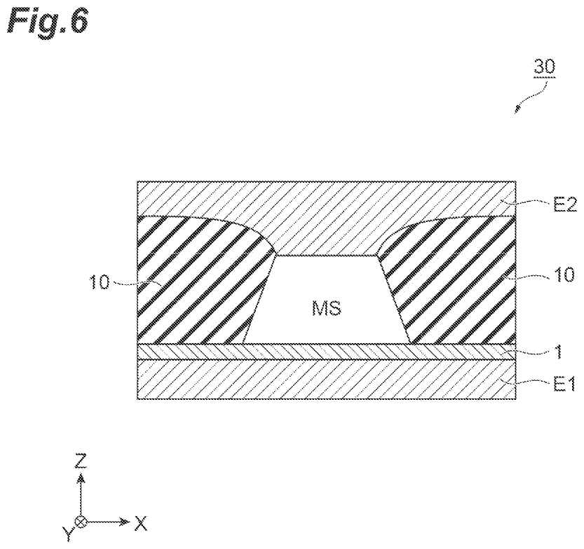

FIG. 6 shows a longitudinal cross-sectional view of the magnetoresistive effect element 30.

The magnetoresistive effect element 30 comprises the first electrode E1, the second electrode E2, the base layer 1, the main stack MS shown in FIG. 1, and side walls 10 arranged outside the main stack MS. The base layer 1 functions as an etching stop layer in the etching process such as RIE (Reactive Ion Etching). The hard mask layer (made of W or Ta) on the main stack MS can protect the main stack during the etching process. After the etching, spaces are formed above the base layer 1. The side walls 10 are formed on the spaces above the base layer 1. The side wall 10 is made of an insulating material such as SiO₂ (silicon dioxide), SiN_{X} (silicon nitride), Al₂O₃ (aluminum oxide), TiO (titanium oxide), TaO_{X} (tantalum oxide), or AlSiO (aluminum silicate). The side wall 10 and other layers of the magnetoresistive element can be formed by sputtering method. A chemical vapor deposition (CVD) method can be also used to form the oxide and/or nitride layers of the magnetoresistive effect element 30.

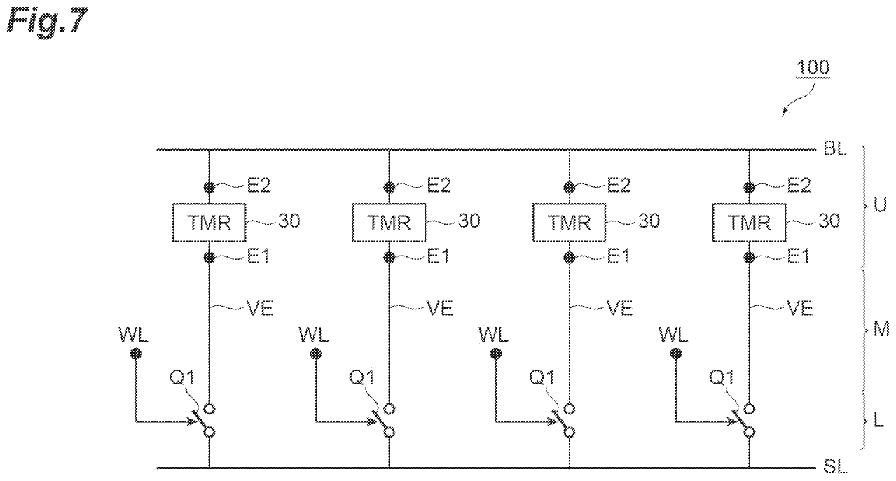

FIG. 7 shows a circuit diagram of the magnetic memory 100.

The magnetic memory 100 comprises a plurality of magnetoresistive effect elements 30 (TMR elements). Each of the magnetoresistive effect elements 30 comprises the above elements shown in FIGS. 1 to 6. The magnetic memory 100 is the MRAM.

The magnetic memory 100 comprises a lower part L, a middle part M, and an upper part U. The lower part L comprises a semiconductor substrate having a plurality of transistors Q1 (switches). The drains of the transistors Q1 are connected to the first electrodes E1 of the magnetoresistive effect elements 30 through via electrodes VE, respectively. The respective sources of the transistors Q1 are connected to a source line SL. The source line SL may be formed in the lower part L, or it may be formed in the middle part M. The respective gates of the transistors Q1 are connected to word lines WL, respectively.

The via electrodes VE and the word lines WL are formed in the middle part M made of an insulating layer. The insulating layer is made of a material such as SiO₂, SiN_{X}, or Al₂O₃. The upper part U is a part positioned above the via electrode VE. The via electrode or wiring is made of a metal such as Cu or Al.

The respective second electrodes E2 of the magnetoresistive effect elements 30 are connected to a bit line BL.

The potential of the word line WL turns on the corresponding transistor Q1, thereby selecting the corresponding magnetoresistive effect element 30. The bit line BL or the source line SL provides a current to the selected magnetoresistive effect element 30. STT-MRAM memorizes the magnetization direction of the magnetization free layer in response the provided current. The magnetic memory 100 comprises magnetoresistive effect elements 30 each having improved characteristics.

When data is written into the memory cells of the magnetic memory 100, a selection voltage is applied to the word line WL that corresponds to the magnetoresistive effect element 30 of a write target. Then, a voltage is applied between the bit line BL and the source line SL when this magnetoresistive effect element 30 is in the ON state. This causes a current, the polarity of which corresponds to the write data (“1” or “0”), to flow through the magnetoresistive effect element 30. A magnitude of the voltage applied at this point is set to a magnitude that may cause spin injection magnetization reversal in a magnetization free layer 4 of the magnetoresistive effect element 30. Accordingly, the magnetization direction of the magnetization free layer 4 is set to a direction corresponding to the write data.

When data is read from the memory cells of the magnetic memory 100, a selection voltage is applied to the word line WL that corresponds to the magnetoresistive effect element 30 of a read target. Then, when this magnetoresistive effect element 30 is in the ON state, a voltage that is smaller than the voltage used during writing is applied between the bit line BL and the source line SL. Accordingly, the data can be read by detecting the current value due to a current of which the magnitude corresponds to data stored in the magnetoresistive effect element 30 flowing between the bit line BL and the source line SL through the magnetoresistive effect element 30.

According to the above magnetoresistive effect element, the ferromagnetic layer 6 has a thickness less than a thickness of the magnetization free layer 4, and the thickness of the ferromagnetic layer 6 may be 0.5 nm or less. The thickness of the ferromagnetic layer 6 is less than a thickness sufficient to cause self-magnetization in the ferromagnetic layer 6. Since the ferromagnetic layer 6 (ferromagnetic material diffusion block layer) can suppress the material diffusion from the magnetization free layer 4 made of ferromagnetic material, the characteristics such as reliability of the magnetoresistive effect element is improved. When the ferromagnetic layer includes Fe and Co, the ferromagnetic layer can suppress the diffusion of these materials.

As stated above, the reference layer 2 includes the first ferromagnetic layer 2A, the second ferromagnetic layer 2C, and the nonmagnetic layer 2B, the tunnel barrier layer includes MgO, the first cap layer includes MgO, and the second cap layer 7 includes the nonmagnetic metal layer. The magnetoresistive effect element 30 can suppress material diffusion while definitely controlling the magnetization direction of the reference layer.

Various modifications to the above embodiments will be readily apparent to those skilled in the art, and the principles defined herein may be applied to other embodiments without departing from the scope of the disclosure. Various features of the described embodiments may be combined. Although individual features may be included in different claims, these may possibly be combined advantageously. It should be appreciated that the present invention should not be construed as limited by such embodiments but, rather, construed according to the following claims.

What is claimed is:

1. A magnetoresistive effect element comprising:
a reference layer;
a magnetization free layer;
a tunnel barrier layer provided between the reference layer and the magnetization free layer;
a first cap layer provided on the magnetization free layer;
a second cap layer; and
a ferromagnetic layer provided between the first cap layer and the second cap layer, the ferromagnetic layer having a thickness that is less than a thickness of the magnetization free layer.

2. The magnetoresistive effect element according to claim 1, wherein the thickness of the ferromagnetic layer is 0.5 nm or less.

3. The magnetoresistive effect element according to claim 1, wherein the thickness of the ferromagnetic layer is less than a thickness sufficient to cause self-magnetization in the ferromagnetic layer.

4. The magnetoresistive effect element according to claim 1, wherein the ferromagnetic layer includes Fe and Co, and a concentration of Co decreases as the ferromagnetic layer approaches the second cap layer.

5. The magnetoresistive effect element according to claim 1, wherein the ferromagnetic layer comprises a plurality of islands distributed two-dimensionally on the first cap layer.

6. The magnetoresistive effect element according to claim 1, wherein the first cap layer comprises an oxide layer, a thickness of the oxide layer being less than a thickness of the tunnel barrier layer.

7. The magnetoresistive effect element according to claim 1, wherein the thickness of the first cap layer is 0.5 nm or less.

8. The magnetoresistive effect element according to claim 1, wherein a cap layer including the first cap layer, the second cap layer, and the ferromagnetic layer does not exhibit a magneto-resistive effect.

9. The magnetoresistive effect element according to claim 1,
wherein the first cap layer includes an oxide of a first metal element;
wherein the tunnel barrier layer includes an oxide of a second metal element; and
wherein the first metal element and the second metal element are identical.

10. The magnetoresistive effect element according to claim 9,
wherein the oxide of the first metal element is MgO; and
wherein the oxide of the second metal element is MgO.

11. The magnetoresistive effect element according to claim 1,
wherein the first cap layer comprises a plurality of islands distributed two-dimensionally on the magnetization free layer.

12. The magnetoresistive effect element according to claim 1,
wherein the first cap layer comprises a plurality of islands distributed two-dimensionally on the magnetization free layer; and
wherein the ferromagnetic layer fills a space between the islands.

13. The magnetoresistive effect element of claim 1,
wherein the second cap layer comprises a nonmagnetic metal layer in contact with the ferromagnetic layer, and
wherein the nonmagnetic metal layer comprises at least one element selected from the group consisting of Ru, Mo, and W.

14. The magnetoresistive effect element according to claim 13, wherein the nonmagnetic metal layer comprises a plurality of metal layers.

15. The magnetoresistive effect element according to claim 13, further comprising a hard mask layer in contact with the nonmagnetic metal layer, wherein the hard mask layer comprises at least one of Ta and W.

16. The magnetoresistive effect element according to claim 1, further comprising:
a first electrode;
a base layer provided between the first electrode and the reference layer; and
a second electrode provided on the second cap layer.

17. The magnetoresistive effect element according to claim 16,
wherein the reference layer includes:
a first ferromagnetic layer;
a second ferromagnetic layer;
a nonmagnetic layer interposed between the first ferromagnetic layer and the second ferromagnetic layer;
wherein the tunnel barrier layer includes MgO;
wherein the first cap layer includes MgO; and
wherein the second cap layer includes a nonmagnetic metal layer.

18. The magnetoresistive effect element according to claim 17,
wherein the base layer comprises:
a first Ta-containing layer provided on the first electrode;
a Ti-containing layer provided on the first Ta-containing layer; and
a second Ta-containing layer provided on the Ti-containing layer.

19. The magnetoresistive effect element according to claim 18,
wherein the base layer comprises:
a metal layer provided on the second Ta-containing layer; and
a NiCr layer provided on the metal layer.

20. A magnetic memory comprising a plurality of magnetoresistive effect elements,
wherein each of the magnetoresistive effect elements comprises:
a reference layer;
a magnetization free layer;
a tunnel barrier layer provided between the reference layer and the magnetization free layer;
a first cap layer provided on the magnetization free layer;
a second cap layer; and
a ferromagnetic layer provided between the first cap layer and the second cap layer, the ferromagnetic layer having a thickness less than a thickness of the magnetization free layer.
